(19) United States
(12) Patent Application Publication
(10) Pub. No.: US 2020/0153238 A1
(43) Pub. Date: May 14, 2020

(54) INTEGRATED FAULT CURRENT RISE LIMITER AND FAULT DETECTION DEVICE FOR DC MICROGRIDS

(71) Applicant: Rolls-Royce North American Technologies Inc., Indianapolis, IN (US)

(72) Inventor: David Loder, Carmel, IN (US)

(73) Assignee: Rolls-Royce North American Technologies Inc., Indianapolis, IN (US)

(21) Appl. No.: 16/184,774

(22) Filed: Nov. 8, 2018

(51) Int. Cl. H02H 7/26; H02H 1/00; H02H 7/28; G01R 15/18; G01R 19/12

(52) U.S. Cl. CPC H02H 7/268; H02H 1/0007; G01R 19/12; H02H 7/28; G01R 15/181; H02H 1/0092

(57) ABSTRACT

A Direct Current fault protection and localization system utilizing a Rogowski coil adapted to perform current limiting on the main power line in the case of a line to line fault.

### BACKGROUND

Direct Current power grids are becoming more prominent in high voltage electrical systems, particularly as modern dc to ac converters are becoming light enough for a single DC microgrid to power multiple ac devices, each operating its preferred frequency, and also allow multiple AC power supplies, operating at various frequencies, to power the DC power grid.

In High Voltage DC electric systems, there is the possibility of a short circuit between the positive and negative DC lines which can lead to capacitive discharge in the system, and the release of stored electricity causing a large current spike which may lead to a catastrophic failure of the system. As a result, limiting or preventing capacitive discharge and fast, reliable fault detection and localization are becoming essential to the ideal operation of HVDC systems.

Solid-state circuit breakers (SSCB) which can break the fault extremely quickly have been suggested to combat capacitive discharge. However, due to a large weight and loss penalty SSCBs may not be the best solution. Others have proposed using various types of fault current rise limiters (FCRL), snubbers, and other devices to simply reduce the peak discharge current, which can be damaging due to high electromagnetic forces and spikes in voltage. However, inductive FCRLs are often very heavy (high current requires large non-saturable core); resistance and/or snubber circuits ahead of a capacitor have an inherent loss penalty; also these system being in series with the High Voltage circuit introduce new point of failure.

A very promising option for detecting and locating dc line-line faults is by monitoring and comparing the di/dt of the dc output line of the converter. Accurate knowledge of the di/dt signature can allow for fast and robust detection with a lower risk of false positives. Furthermore, the di/dt signature is strongly related with distance to the fault, which can be used to locate the faulted branch.

Unfortunately, current transformers add appreciable weight to the system, especially for accurate measurement of high fault currents without saturation, and may not offer the bandwidth necessary to provide sufficient resolution for these high speed fault events. In addition, computing di/dt accurately is processor intensive and is prone to issues such as a missed or incorrect sample which can lead to detection failures or false positives.

It would be advantageous to perform the functions of fault current rise limiting, fault detection, and fault localization with a single light weight component.

### SUMMARY

The disclosure presents A DC fault protection system which may include a DC line a fault processor; a fault current rise limiter. The fault current rise limiter may include a coil of electrically conducting material encircling the DC line, the coil may include at least two leads; a clamping circuit between the at least two leads of the coil; the coil being inductively coupled to the DC line and conductively insulated from the DC line; the at least two leads operably coupled to the fault processor.

In one embodiment the coil is a Rogowiski coil. In another embodiment the clamping circuit may include devices selected from the group of TVS diodes and MOVs. Another embodiment may include a signal conditioning device between the at least two leads and the fault processor. Yet another embodiment may include a breaker on the DC line. In a further embodiment at least two leads are operably connected to the breaker and a voltage across the at least two leads triggers the breaker. In another embodiment the fault processor is a DSP or FPGA. In yet another embodiment the DC line is electrically connected between a HVDC grid and a DC power supply. Other embodiments may include an auxiliary power source for powering the breaker. In some embodiments the breaker is a hybrid relay, contactor or solid state breaker. In yet a further embodiment the Rogowski coil limits a rate of change of current in the DC line and outputs an electrical signal to the fault processor, the electrical signal representative of the rate of change of current. In other embodiments the fault current rise limiter may further include a plurality of coils.

The disclosure also presents a fault protected DC circuit, may include a DC line between a power source and a HVDC grid; a Rogowski coil having an output connected to a processing unit; the DC line passing through a core of the Rogowski coil; and, a clamping circuit on the output of the Rogowiski coil; the Rogowski coil may limit the current rise rate in the DC line, and the output of the Rogowski coil may be reflective of the current rise rate.

The disclosure also presents a method of protecting a DC line against a fault resulting in an increasing current in the DC line, which may include measuring the rate of increase in the increasing current with a Rogowski coil; outputting from the Rogowski coil an electrical signal reflective of the rate of increase; limiting the rate of increase as a function of current induced in the Rogowski coil as a result of the increasing current; analyzing the electrical signal in a processor; and determining a characteristic of a fault based upon the analyzing.

In some embodiments of the method may include tripping a breaker in the DC line in response to the characteristic. In some embodiments the characteristic of the electrical signal may be a function of the location of a fault. In some embodiments the method may further include tripping a breaker in the DC line in response to the electrical signal. In a further embodiment the step of measuring the rate of increase comprises inductively coupling the Rogowski coil to the DC line and conductively insulating the Rogowski coil from the DC line. Other embodiments may further include clamping the Rogowski coil. Yet other embodiments may include determining the location of the fault based on the characteristic.

### BRIEF DESCRIPTION OF THE DRAWINGS

The following will be apparent from elements of the figures, which are provided for illustrative purposes.

FIG. 1. Illustrates an embodiment of the current limiting system.

FIG. 2. Illustrates a second embodiment of the system with current limiting and a breaker.

FIG. 3. Illustrates the response of the fault current during a line to line fault.

FIG. 4. Illustrates the response of the fault current during a line to line fault with the current limiting system applied.

The present application discloses illustrative (i.e., example) embodiments. The claimed inventions are not limited to the illustrative embodiments. Therefore, many implementations of the claims will be different than the illustrative embodiments. Various modifications can be made to the claimed inventions without departing from the spirit and scope of the disclose. The claims are intended to cover implementations with such modifications.

### DETAILED DESCRIPTION

For the purposes of promoting an understanding of the principles of the disclosure, reference will now be made to a number of illustrative embodiments in the drawings and specific language will be used to describe the same.

The present disclosure is directed to systems and methods for fault protection in High Voltage Direct Current (HVDC) electrical systems.

A Rogowski coil is lightweight current measurement device. However, a Rogowski coil does not directly measure current, but rather its derivative

$$( {v}_{out} \sim \frac{di}{dt} ) .$$

Integrator circuits are typically used to condition the raw Rogowski coil output into a true current measurement. A Rogowski coil may be used to physically measure the derivative of current on the dc line, while also connecting the secondary terminals of the Rogowski coil to a voltage suppression device (transient-voltage-suppression diode (TVS diode) or a metal-oxide varistor (MOV)) in order to limit the fault current rise. This is highly advantageous as Rogowski coils are highly linear and have high bandwidth (no saturation due to air-core construction). Moreover, the FCRL devices (TVS diodes or MOVs) are isolated from main power circuit and thus reduce potential points of failure. In addition, the direct physical measurement of the current derivative, as described herein, improves robustness of fault detection and location.

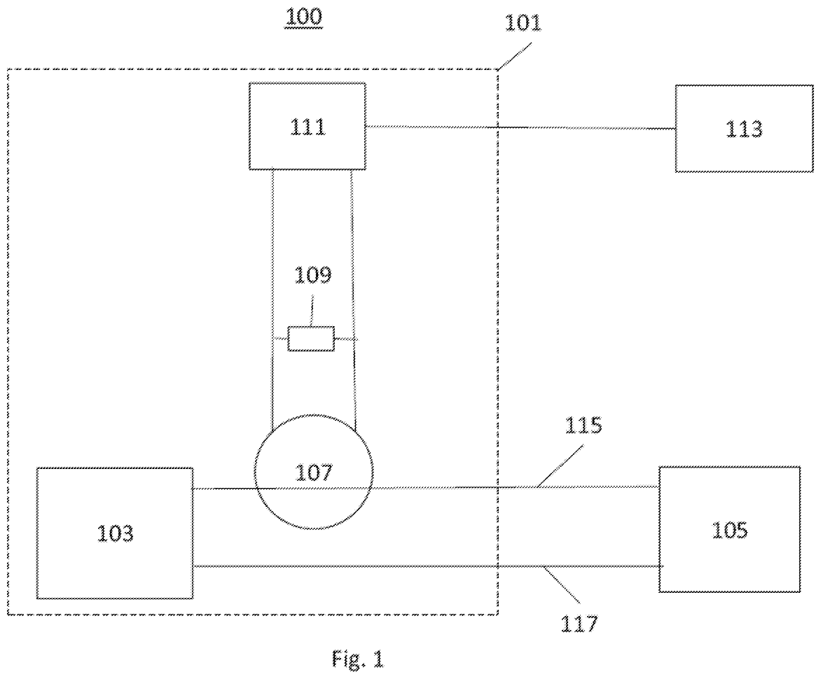

As shown in FIG. 1 a power converter enclosure 101 may include power electronics 103, a Rogowski coil 107, and a signal conditioner 111. The power electronics 103 sends main DC power along a main power line 115 to the HVDC grid 105. A return line 117 runs from the HVDC grid back to the power electronics 103. The Rogowski coil 107 is installed around the main power line 115 and measures the timed rate of change of the main line current. As a line to line fault occurs, the current in the main power line will increase. The increase in current will increase the strength of magnetic field around the line, which will interact with the coil producing an increase in voltage in the coil proportional to the timed rate of change of the main line current.

The signal conditioner will supply an integrated and scaled current signal to the Fault Detection & Location module 113. The Fault detection & logic circuit may be implemented with a Digital Signal Processor (DSP), Field Programmable Gate Array (FPGA), or similar logic processing device. Due to rate of change of the current being strongly related to the distance to the fault, the fault detection & location module 113 may approximate the location of the fault. Fault current signatures may be used by the fault detection & location logic circuit to not only approximate the distance to the fault but also the faulted component as the different components will have different signatures due to different branch impedances.

The Rogowski coil may also have a voltage clamping device 109 like a TVS diode or MOV attached to its positive and negative terminals. During a fault event, the rapid rise in current will cause the Rogowski coil output voltage to rise above the breakdown voltage of the voltage clamping device 109. At this point, the rise in the main fault current (di/dt) will be clamped as a function of the mutual inductance and the breakdown voltage. Fault energy will be dissipated as losses within the clamping device and Rogowksi coil, and the peak fault current will be reduced. Reduction of the peak fault current is critical for relaxing stresses arising from large electromagnetic forces, and rapid heating. It also allows more time to detect, locate, and isolate the fault before equipment is damaged.

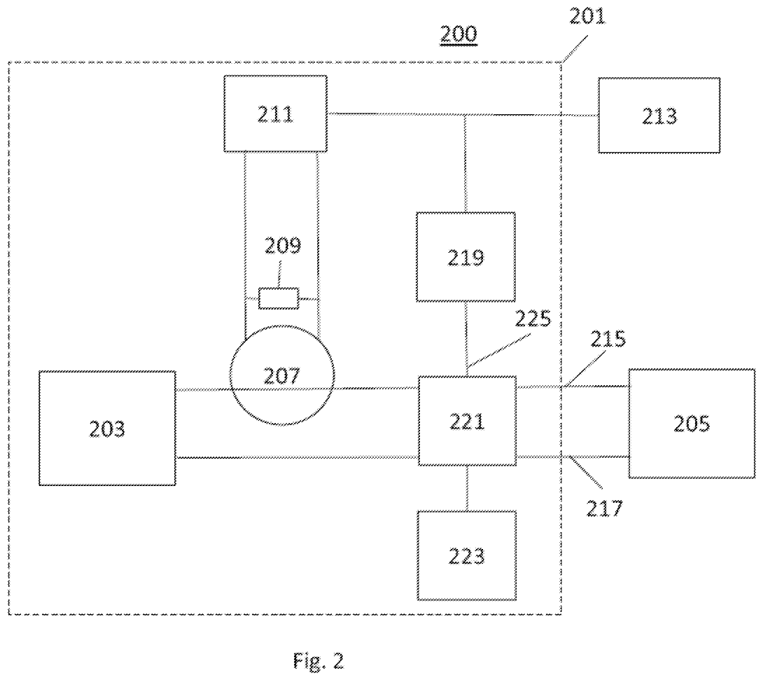

The di/dt output measurement of the Rogowski coil can also be used to directly trigger a breaking device through a signal conditioning unit, resulting in rapid fault detection and isolation. FIG. 2 shows an alternate embodiment in which the Rogowski coil 207 is used to activate a protective device. As can be seen in FIG. 2, a breaker 221 is installed along the main line and return line, and is housed within the power converter enclosure 201. The low voltage analog signal can be sent to both a centralized detection & location logic circuit 213 that is external to the power converter, as well as a signal processor 219 that is internal to the power converter. When a line to line fault occurs the coil may register the increase in the rate of change of the main line current. The signal conditioner 211 may supply a conditioned measurement signal to the signal processor 219, which will send a trigger signal to the breaker, activating the breaker 221 in the event of a fault. In some embodiments, to the output of the signal conditioner 211 may be used to activate the breaker 221 directly, in which case signal processing control logic may not be necessary.

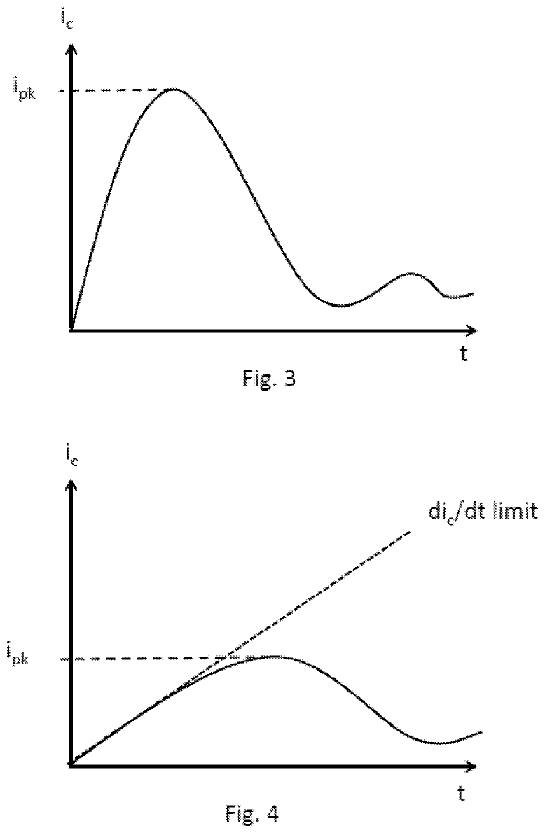

FIG. 3 qualitatively shows the current response during a line to line fault. As can be seen a large current rise occurs shortly after initiation of the fault, due in part to capacitive discharge, which then tapers off over a short period of time. FIG. 4 qualitatively shows the same fault but with current limiting in accordance with the disclosure applied. Current rises linearly at a lower rate due to interaction with the Rogowski coil and peaks at a much lower current than if the current limiting was not applied.

Although examples are illustrated and described herein, embodiments are nevertheless not limited to the details shown, since various modifications and structural changes may be made therein by those of ordinary skill within the scope and range of equivalents of the claims.

What is claimed is:

1. A DC fault protection system comprising:
a DC line;
a fault processor;
a fault current rise limiter, the fault current rise limiter comprising:
a coil of electrically conducting material encircling the DC line; the coil comprising at least two leads;
a clamping circuit between the at least two leads of the coil;
the coil being inductively coupled to the DC line and conductively insulated from the DC line;
the at least two leads operably coupled to the fault processor.

2. The system of claim 1, wherein the coil is a Rogowiski coil.

3. The system of claim 1, wherein the clamping circuit comprises devices selected from the group of TVS diodes and MOVs.

4. The system of claim 1, further comprising a signal conditioning device between the at least two leads and the fault processor.

5. The system of claim 1, further comprising a breaker on the DC line.

6. The system of claim 5, wherein the at least two leads are operably connected to the breaker and a voltage across the at least two leads triggers the breaker.

1. tem of claim 1, wherein the fault processor is a DSP or FPGA.

8. The system of claim 1, wherein the DC line is electrically connected between a HVDC grid and a DC power supply.

9. The system of claim 6, further comprising an auxiliary power source for powering the breaker.

10. The system of claim 6, wherein the breaker is a hybrid relay, contactor or solid state breaker.

11. The system of claim 2, wherein the Rogowski coil limits a rate of change of current in the DC line and outputs an electrical signal to the fault processor, the electrical signal representative of the rate of change of current.

12. The system of claim 1, wherein the fault current rise limiter further comprises a plurality of coils.

13. A fault protected DC circuit, comprising:
a DC line between a power source and a HVDC grid;
a Rogowski coil having an output connected to a processing unit; the DC line passing through a core of the Rogowski coil; and,
a clamping circuit on the output of the Rogowiski coil;
wherein the Rogowski coil limits the current rise rate in the DC line, and the output of the Rogowski coil is reflective of the current rise rate.

14. A method of protecting a DC line against a fault resulting in an increasing current in the DC line, the method comprising:
measuring the rate of increase in the increasing current with a Rogowski coil;
outputting from the Rogowski coil an electrical signal reflective of the rate of increase;
limiting the rate of increase as a function of current induced in the Rogowski coil as a result of the increasing current;
analyzing the electrical signal in a processor;
and determining a characteristic of a fault based upon the analyzing.

15. The method of claim 14, further comprising tripping a breaker in the DC line in response to the characteristic.

16. The method of claim 14, wherein the characteristic of the electrical signal is a function of the location of a fault.

17. The method of claim 14, further comprising tripping a breaker in the DC line in response to the electrical signal.

18. The method of claim 14, wherein the step of measuring the rate of increase comprises inductively coupling the Rogowski coil to the DC line and conductively insulating the Rogowski coil from the DC line.

19. The method of claim 14, further comprising clamping the Rogowski coil.

20. The method of claim 16, further comprising determining the location of the fault based on the characteristic.
